(19) United States
(12) Patent Application Publication
(10) Pub. No.: US 2025/0253156 A1
(43) Pub. Date: Aug. 7, 2025

(54) DEPOSITION AND ETCHING FOR SELECTIVE REMOVAL OF DEPOSITED DIELECTRIC FILM FROM TOPS OF FINS

(71) Applicant: Applied Materials, Inc., Santa Clara, CA (US)

(72) Inventors: Srinivas D. Nemani, Sunnyvale, CA (US); Mang-Mang Ling, San Jose, CA (US); Jong Mun Kim, San Jose, CA (US); Taiki Hatakeyama, Cupertino, CA (US); Bhargav Citla, Fremont, CA (US); Ellie Y. Yieh, San Jose, CA (US)

(21) Appl. No.: 18/435,853

(22) Filed: Feb. 7, 2024

(51) Int. Cl. H01L 21/311; H01J 37/32

(52) U.S. Cl. CPC H01L 21/31116; H01J 37/32449; H01L 21/31144; H01J 2237/332; H01J 2237/3341

(57) ABSTRACT

A method of removal of a dielectric film on a substrate includes depositing a protective polymer coating onto a dielectric film on top surfaces of fins and sidewalls and bottoms of trenches formed in a substrate, and reactive ion etching the substrate at processing conditions selected so as to preferentially remove the dielectric film and protective polymer coating from the top surfaces of the fins in comparison to the dielectric film and protective polymer coating at the bottom of the trenches.

### TECHNICAL FIELD

The present disclosure relates semiconductor processing, and in particular to etching of a silicon nitride layer in a trench.

### BACKGROUND

One fabrication technique used during integrated circuit fabrication is to form a trench in a substrate by depositing a masking layer on the substrate, etch apertures through the masking layer to create a hard mask over the substrate, and then etch the substrate in regions that are not covered by the hard mask to form trenches. In some cases the substrate can be a silicon wafer, but in some cases the substrate can include additional layers disposed on the wafer. In either case, the trenches can then be coated with a dielectric film, e.g., a silicon nitride film. For some applications, multiple trenches are formed in parallel and proximity, leaving islands in the form of pillars or walls between the trenches. In this case, the silicon nitride film will cover the sides and bottom of each trench, as well as the top surface of the islands (i.e., the top surface of the hard mask).

### SUMMARY

In another aspect, a method of modifying a dielectric film on a substrate includes: on a substrate that includes a wafer, a hardmask mask layer on the wafer, and a plurality of trenches that extend through the hardmask mask layer and into the wafer to form a plurality of fins, and a dielectric film that coats top surfaces of the fins and sidewalls and bottom of the trenches and forms a filled region at the bottom of the trenches, depositing a protective polymer coating onto the dielectric film such that the protective polymer coating covers the top surfaces of the fins and the sidewalls and bottom of the trenches, and plasma etching the substrate at processing conditions selected so as to remove the protective polymer coating and a portion dielectric film at the bottom of the trenches so as to increase the concavity of the top surface of the filled region.

In one aspect, a method of removal of a dielectric film on a substrate includes on a substrate that includes a wafer, a hardmask mask layer on the wafer, a plurality of trenches that extend through the hardmask mask layer and into the wafer to form a plurality of fins, and a dielectric film that coats top surfaces of the fins and sidewalls and bottoms of the trenches, depositing a protective polymer coating onto the dielectric film such that the protective polymer coating covers the top surfaces of the fins and the sidewalls and bottom of the trenches, and reactive ion etching the substrate at processing conditions selected so as to preferentially remove the dielectric film and protective polymer coating from the top surfaces of the fins in comparison to the dielectric film and protective polymer coating at the bottom of the trenches.

In another aspect, a plasma processing system includes a vacuum chamber, a support to hold a substrate in the vacuum chamber, a fluorocarbon gas source, a hydrogen gas source, one or more RF power sources to apply RF power to the vacuum chamber, and a controller configured to cause the system to perform these methods.

Implementations of either aspect may include one or more of the following features. The dielectric film may be a silicon nitride film, the hardmask mask layer may be a silicon nitride, and the protective polymer coating may be a fluocarbon polymer. Performing the reactive ion etch may remove a portion of the hardmask mask layer from the top of the fins. Depositing the protective polymer coating and plasma etching the substrate may be performed in-situ in a processing chamber without removing the substrate from the chamber.

Advantages may optionally include, but are not limited to, one or more of the following. A dielectric film, e.g., a silicon nitride film, can be removed from the top of the fins while generally preserving the dielectric material at the bottom of the trench. The thickness profile of a dielectric film at the bottom of the trench can be controlled between an incoming flat or convex shape and a concave shape. The process includes depositing a protective polymer film, and deposition of the polymer film and etching of the dielectric film can be performed in the same chamber, improving throughput and reducing processing complexity and need for additional equipment.

The details of one or more implementations are set forth in the accompanying drawings and the description below. Other aspects, features, and advantages will be apparent from the description and drawings, and from the claims.

### DESCRIPTION OF DRAWINGS

FIG. 1A is a schematic cross-sectional view of a portion of a substrate having a trench with silicon nitride forming a relatively flat surface at the bottom of the trench.

FIG. 1B is a schematic cross-sectional view of a portion of a substrate having a trench with silicon nitride forming a convex surface at the bottom of the trench.

FIG. 1C is a schematic cross-sectional view of a portion of a substrate having multiple trenches that form multiple fins.

FIG. 1D is an image of a cross-section of a portion of a trench in a substrate. FIG. 2 is a flow chart illustrating a process of modifying the silicon nitride layer.

FIGS. 3A-3D are schematic cross-sectional views of the substrate during the process of modifying the silicon nitride layer.

FIG. 4 is a schematic cross-sectional side view of a processing chamber that can be used to perform the process of FIGS. 2 and 3A-3D.

Like reference symbols in the various drawings indicate like elements.

### DETAILED DESCRIPTION

When a dielectric film, e.g., silicon nitride, is deposited onto the surfaces of a deep trench, the dielectric material at the bottom of the trench will have a cross-sectional profile. This cross-sectional profile, which can also be called a “contour,” might have a generally flat section across the bottom of the trench and relatively sharp corners at the sidewalls. As integrated circuits become smaller, topographical control becomes more critical, and even the dielectric material at the bottom of the trench may need a more precisely controlled contour. Formation of such high aspect ratio trenches, particularly in a large array of trenches, is of particular importance in the fabrication of next-generation transistors, e.g., gate-all-around (GAA) field effect transistors (FETs).

This disclosure concerns a technique in which the profile of the dielectric material, e.g., silicon nitride, at the bottom of the trench is modified, thus permitting selection of the profile as concave instead of the incoming flat or convex configuration. This disclosure also concerns a technique in which the dielectric material, e.g., silicon nitride, is removed from the top of the fins with limited removal at the bottom of the trench.

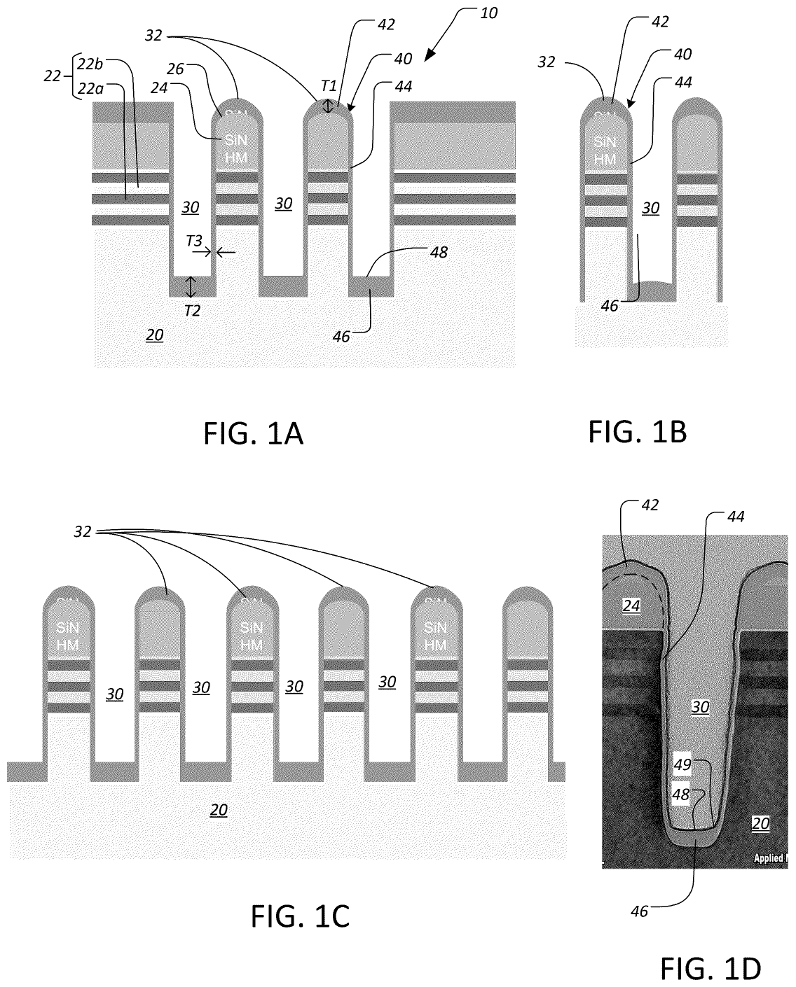

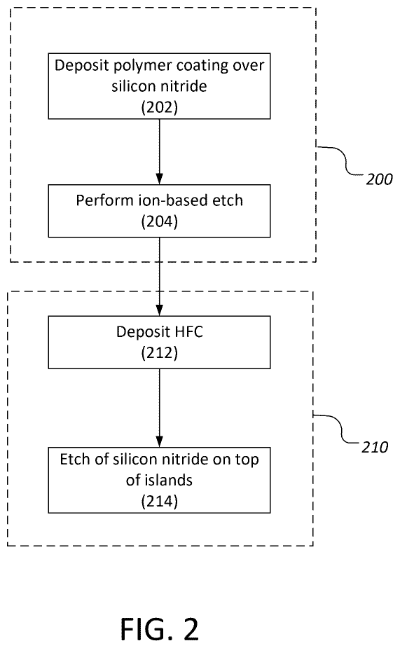

FIG. 1A illustrates a portion of a substrate 10 that includes a semiconductor wafer 20 and optional additional layers 22 deposited on the wafer 20. For example, for a gate-all-around device, the additional layers 22 can include alternating layers 22a, 22b of SiGe and Si, respectively. The top surface of the wafer 20 and optional additional layers 22 can be covered by a hardmask mask layer 24, e.g., a silicon nitride mask layer.

Trenches 30 are formed in the substrate 10, including through the apertures in the mask layer 24 and into the wafer 20 and optional additional layers 22. These trenches 30 define fins 32, e.g., the fins of a GAA FET, that are separated by adjacent trenches 30. The trenches can be relatively deep, e.g., an aspect ratio of 4:1 or greater, such as up to 25:1, e.g., up to 10:1. Similarly, the fins can be relatively thin, e.g. an aspect ratio of 4:1 or greater, such as up to 25:1, up to 10:1. In addition, although only two fins are shown in FIG. 1A, there could a large number of fins uniformly spaced in an array, e.g., as shown in FIG. 1C. Due to the etching of the trench, the top surface 26 of the mask layer 24 on the fins 32 can be rounded.

A relatively thin dielectric film 40, e.g., a silicon nitride film, coats the substrate 10; it coats the sides of the trenches without filling the trenches. This silicon nitride film 40 can form a rounded top 42 on the top surface of the fins 32, i.e., on top of the mask layer 24. The silicon nitride film 40 also forms a coating 44 on the sidewalls of the trench 30 that is thinner than the portion at the rounded top. In addition, the silicon nitride film 40 creates a filled portion 46 at the bottom of the trench 30. The thickness of the rounded top 42 and filled portion 46 of the silicon nitride can be about 1.5 to 4 times the thickness of the silicon nitride coating 44 on the sidewalls. For example, the silicon nitride layer 40 can have an initial thicknesses (prior to the process described below) T1, T2, and T3 at the rounded top 42 of about 10-15 nm, at the bottom of about 8-12 nm, and along the sidewalls 44 of about 2-6 nm, e.g., 2-4 nm, respectively.

This structure can be formed by depositing a layer of hardmask material onto the top surface of the wafer 20 and optional additional layers 22, using photoresist-based photolithographic techniques to etch apertures through the hardmask material, and then stripping the photoresist to leave the resulting mask layer 24 of the hardmask material on the substrate 10. The substrate 10 can then be subjected to an etching process to etch away the exposed portion of the substrate 20 and optional additional layers 22, thus forming recesses in the wafer 20, thereby providing the trenches as a combination of the apertures through the mask layer 24 and optional additional layer 22 and the recesses in the wafer 20. The substrate can then be coated with the silicon nitride layer 40.

A standard manufacturing process generates a filled portion 46 at the bottom of the trench that has an upper surface 48 that is either generally flat (as shown in FIG. 1A) or convex (as shown in FIG. 1B). An image of a cross-section of a portion of a manufactured substrate in which the filled portion 46 of silicon nitride has a “generally flat” upper surface 48 and forms a “relatively sharp” corner 49 at the intersection with the side wall is shown in FIG. 1D. The boundary between the mask layer 24 and the silicon nitride coating 40 at the rounded top 24 is shown with a phantom line.

As described below, the profile of the silicon nitride layer 40 in the filled portion 46 at the bottom of the trench 30 can be modified, thus permitting selection of the profile as concave instead of the incoming flat or convex configuration.

FIG. 2 illustrates a method that includes a topographic control process (200) to control the contour of the silicon nitride layer at the bottom of the trench, and a selective removal process (210) that preferentially removes silicon nitride from the tops of the fins as opposed to removing silicon nitride from the bottom of the trenches. The topographic control process (200) includes depositing a first protective film (202) and then performing a reactive ion etch (204). The selective removal process (210) includes depositing a second protective film (212) and then performing a plasma mode etch (214). Each process (200), (210) could be used independently; they need not be used in combination.

As noted above, for topographic control, a two-step approach can be used that includes forming a first polymer protection layer (202), and then removal of the SiN using an etch process that has low selectivity of the top/bottom (204). In particular, a single chamber can be operated first in a deposition mode to form the polymer protection layer, and then in an etch mode that etches the polymer protection layer and the silicon nitride at the bottom of the trench (as well as on the tops of the fins).

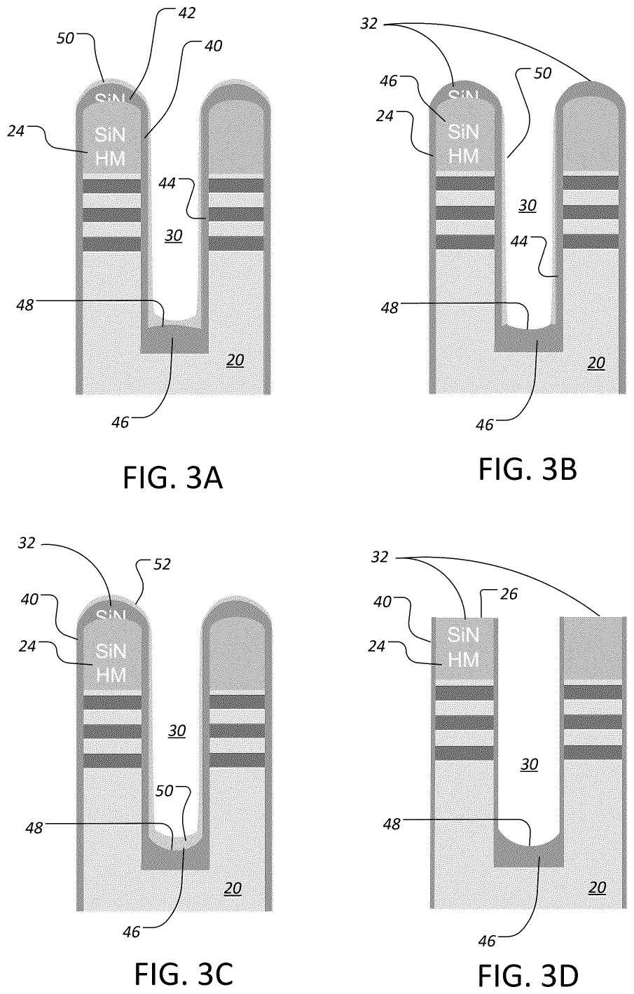

Referring to FIGS. 2 and 3A, a carbon-containing layer 50 is deposited over the silicon nitride layer 40 (step 202). In particular, the carbon-containing layer 50 can be a fluorocarbon or fluoropolymer, e.g., a hydrogenated fluorocarbon or hydrogenated fluoropolymer. Specifically, the carbon-containing layer 50 can be CFx. The carbon-containing layer 50 can be deposited using an isotropic chemical vapor deposition, in particular plasma-enhanced chemical vapor deposition system.

The process can be performed at a pressure of 0.5-3.0 Torr, e.g., 0.5-2.0 Torr, an RF power of 50-300 W, a typical megahertz driving frequency, e.g., 27 MHz, and a substrate temperature of 400-500° C. The flow rate of the CF₄ and the H₂ can be approximately equal, e.g., in a range of 25-100 sccm and within 10% of each other. An inert gas, e.g., Ar, can be provided at a flow rate 3-10 times that of the combined flow rates of the CF₄ and the H₂, e.g., 200-1000 sccm. The process can run for 15-90 seconds.

Referring to FIGS. 2 and 3B, the substrate is then subjected to an anisotropic dry etch (step 204). Due to the directionality of the etch, the carbon-containing layer 50 is removed from the top surface of the fin 32 and the upper surface 48 of the filled portion 46 at the bottom of the trench 30. On the other hand, by running the process at moderate selectivity of the carbon-containing material versus the silicon nitride, after removal of the carbon-containing layer 50 at the bottom of the trench, the etching can continue into the silicon-nitride material, thus modifying the profile of the silicon nitride of the filled portion 46. In particular, if the upper surface 48 begins as generally flat, the etching will form a concave surface, with a degree of concavity depending on the etch time. If the upper surface 48 begins as convex, the etching can form a generally flat surface or a concave surface, depending on the etch time. This etching step could also remove material from the rounded tops, but this is acceptable as this silicon nitride is to be removed anyway.

The anisotropic etch can be performed in the same plasma chamber and using the same gas components, e.g., H₂ and CF₄, as the deposition process for the carbon-containing layer 50. However, simply changing the pressure, power, and/or gas flow ratio can change the deposition process to an etching process. In particular, to achieve an isotropic etch, the process can be run at relatively higher power than the deposition process, e.g., at 400-500 W instead of 100 W. In addition, the process can be run at equal and lower power pressure.

The etching process can be performed at a pressure of 0.3-1.0 Torr, an RF power of 100-1000 W, (e.g., 300-1000 W), a typical megahertz driving frequency, e.g., 27 MHz, and a substrate temperature of 400-500° C. The flow rate of the CF₄ can be two to four times that of the H₂, e.g., the flow rate of the CF₄ can be about 60-100 sccm and the flow rate of the H₂ can be about 15-50 sccm. An inert gas, e.g., Ar, can be provided at flow rate 5-20 times that of the combined flow rate of the CF₄ and the H₂, e.g., 200-1000 sccm. The process can run for 30-150 seconds.

If any of the first carbon-containing layer 50 remains on the substrate, it can be stripped.

For a selective top SiN removal, a two-step approach can be used that includes forming a polymer protection layer (212), and then removal of the SiN using an etch process that has top/bottom selectivity (214). In particular, a single chamber can be operated first in a deposition mode to form the polymer protection layer, and then in a selective etch mode that preferentially etches the polymer protection layer and the silicon nitride on the tops of the fins.

Referring to FIGS. 2 and 3C, a second carbon-containing layer 52 is deposited over the silicon nitride layer 40 (step 212). In particular, the second carbon-containing layer 52 can also be a fluorocarbon or fluoropolymer, e.g., a hydrogenated fluorocarbon or hydrogenated fluoropolymer. Specifically, the carbon-containing layer 50 can be CFx. The second carbon-containing layer 52 can be deposited using an isotropic chemical vapor deposition, in particular plasma-enhanced chemical vapor deposition system.

The process can be performed at a pressure of 2-4 Torr, an RF power of 50-300 W, a typical megahertz driving frequency, e.g., 27 MHz, and a substrate temperature of 400-500° C. The flow rate of the CF₄ and the H₂ can be approximately equal, e.g., in a range of 25-100 sccm and within 10% of each other. An inert gas, e.g., Ar, can be provided at a flow rate 3-10 times that of the combined flow rates of the CF₄ and the H₂, e.g., 200-1000 sccm. The process can run for 15-60 seconds.

The reaction can be described by the following:
H₂ molecule dissociation:
   H₂→2H, ΔH=436 kJmol−1
Hydrogen Dissociation from H-Rich PECVD SiN: H Film
   Si—H+N—H→2 Si—H+H₂, energy change ˜−1.86 eV
CFx Polymer Formation
   CF₄₊H→HF+CF₃, reaction enthalpies ˜−26.3 KJ/mol
   2CF₄+H₂→CHF₂+CF₂+2F
   SiN+CF₄+H₂→CFx+HCN+FCN+HF+SiFx (Volatile)

The CFx is thus deposited to form a thin layer, e.g., ˜1 nm thick, of polymer.

Without being limited to any particular theory, this process has a relatively low etch rate of the underlying SiN because i) the CF4 does not easily to react with the SiN due to the formation of the thin polymer layer protection, and ii) F₂+H₂→2HF reaction increases with higher power, so the excited H starts to scavenge fluorine.

Referring to FIGS. 2 and 3D, the substrate is then subjected to another plasma etch (step 214). In this step, the process parameters are set such that, in conjunction with the high aspect ratio of the trench, the silicon nitride and carbon-containing layer at the top of the fin 30 is preferentially etched in comparison to the silicon nitride and carbon-containing layer at the bottom of the trench. As a result, both the silicon nitride film 40 and a portion of the hard mask 24 on the top of the fins 32 can be removed. This can leave the fins with a more planar top surface 26.

As compared to the depositing the polymer protective layer, the selective etching step is performed at a significantly lower pressure, e.g., by a factor of 3-6, at a higher power, e.g., by a factor of 3-8, and with a higher percentage of CF₄.

In comparison to the etch for topographic control (in step 204), the etch for selective removal (in step 214) can be conducted at higher pressure.

The selective etching process can be performed at a pressure of 0.3-1.0 Torr, an RF power of 300-1000 W, a typical megahertz driving frequency, e.g., 27 MHz, and a substrate temperature of 400-500° C. The flow rate of the CF₄ can be two to four times that of the H₂, e.g., the flow rate of the CF₄ can be about 60-100 sccm and the flow rate of the H₂ can be about 15-50 sccm. An inert gas, e.g., Ar, can be provided at flow rate 5-20 times that of the combined flow rate of the CF₄ and the H₂, e.g., 200-1000 sccm. The process can run for 30-150 seconds.

The reaction can be described by the following:
CF₄ Dissociation (Resulting in More Free Fluorine)
   CF₄→CF₃₊F, reaction enthalpies ˜539.8 KJ/mol
   CF₄ can dissociate at higher RF power condition
Hydrogen Dissociation from H-rich PECVD SiN: H Film
   Si—H+N—H→2 Si—H+H₂, energy change ˜−1.86eV
CF₄ reaction with SiN
Spontaneous Reaction of Free Fluorine with SiN
   12F+Si3N₄→3 SiF₄+2 N₂

Without being limited to any particular theory, this process has a higher etch rate of the SiN because i) the CF₄ dissociation (which results in more free fluorine) can occur due to higher RF energy, ii) the resulting free fluorine will have higher energy, which increases the probability of fluorine radicals going deeper into SiN and reacting with Si, and iii) the hydrogen disassociation increases outflux of hydrogen from SiN and creates extra dangling bonds. In addition, still without being limited to any particular theory, free fluorine reacts very readily, and therefor is more likely to react with the nitride at the top of the fins than at the bottom of the trench simply because the longer distance results in a longer travel time to the bottom of high aspect ratio trench.

If any of the second carbon-containing layer 52 remains on the substrate, it can be stripped.

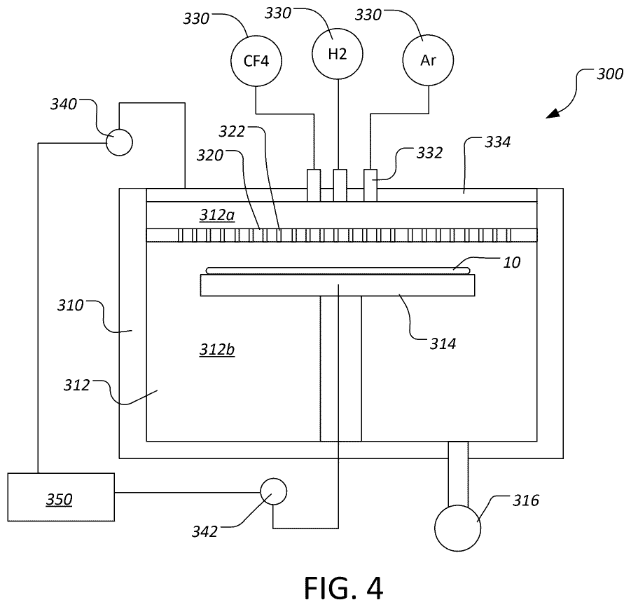

FIG. 4 illustrates an example of a plasma reactor 300 that can be used to carry out the method. Chamber walls 310 enclose a processing chamber 312 in which a pedestal 314 can support the substrate 10. A vacuum pump 316 can create vacuum conditions in the chamber 312 suitable for plasma processing, e.g., 0.1 to 5 Torr. A faceplate 320 with apertures 322 therethrough can extend across the chamber 312 above the pedestal 214, dividing the chamber 312 into an upper portion 312a and a lower portion 312b. Process gasses from process gas sources 330 can flow into the upper chamber 312a through ports 332 in a chamber lid 334. The process gas sources 330 can include a CF₄ source, a H₂ source and an inert gas source, e.g., an Ar source. Process gas sources can be a dedicated canister containing the gas, or a facilities line. The process gas sources can include fluid delivery lines and valves to control the flow rate from of gas into the chamber.

RF power can be applied by an RF source 340 to the chamber lid 334 and/or RF power can be applied by an RF source 342 to the pedestal 314 in order to generate a plasma. Alternatively or in addition, coils can surround and/or be placed above the chamber 312 to generate an inductively coupled plasma.

A controller 350, can be coupled to the RF sources 340, 342 in order to control the applied RF power, to the vacuum pump 316 to control the pressure in the chamber 312, and to the process gas sources 330 to control the respective flow rates of the respective process gasses. Thus, the controller 350 can operate the plasma reactor according to a process recipe to carry out the methods described above.

The 350 controller can include a central processing unit (CPU), a memory, and support circuits, e.g., input/output circuitry, power supplies, clock circuits, cache, and the like. The memory is connected to the CPU. The memory is a non-transitory computable readable medium, and can be one or more readily available memory such as random access memory (RAM), read only memory (ROM), floppy disk, hard disk, or other form of digital storage. In addition, the controller 350 can be implemented as a single computer, or the controller could be a distributed system, e.g., including multiple independently operating processors and memories.

The plasma reactor 300 can include other components, such as a heater embedded in the pedestal or positioned near the floor of the chamber, lift pins in the pedestal, a slit valve for a robot arm to insert the substate onto the pedestal, etc.

### EXAMPLE

The protective polymer film was deposited (for step 212) in a Precision-XP chamber at a pressure of 3 Torr, an RF power of 100W, an RF frequency of 27 MHz, and with a substrate temperature of 450° C. The flow rate of CF₄ was 50 sccm, the flow rate of H₂ was 50 sccm, and the flow rate of Ar was 500 sccm. The process was run for 30 seconds.

The selective etching of the silicon nitride at the top of the fins (for step 214) was performed in a Precision-XP chamber at a pressure of 0.5 Torr, an RF power of 500W, an RF frequency of 27 MHz, and with a substrate temperature of 450° C. The flow rate of CF₄ was 75sccm, the flow rate of H₂ was 25 sccm, and the flow rate of Ar was 500 sccm. The process was run for 90 seconds.

A number of embodiments have been described. However, many variations are possible. For example, rather than the complicated channel and fin shapes described above, the fins can be simple linear stripes with a width selected to provide the desired percentage of contact area. For example, the trailing and leading edge of each fin can be provided by two parallel linear segments. The edges can be rounded at the inner and outer diameter surfaces.

In addition, although the description above has focused on the dielectric film 40 being a silicon nitride film, the process can is applicable to dielectric films of other compositions, e.g., silicon oxide.

Thus, the scope of the invention is defined by the appended claims.

What is claimed is:

1. A method of removal of a dielectric film on a substrate, the method comprising:
on a substrate that includes a wafer, a hardmask mask layer on the wafer, and a plurality of trenches that extend through the hardmask mask layer and into the wafer to form a plurality of fins, and a dielectric film that coats top surfaces of the fins and sidewalls and bottoms of the trenches, depositing a protective polymer coating onto the dielectric film such that the protective polymer coating covers the top surfaces of the fins and the sidewalls and bottom of the trenches; and
reactive ion etching the substrate at processing conditions selected so as to preferentially remove the dielectric film and protective polymer coating from the top surfaces of the fins in comparison to the dielectric film and protective polymer coating at the bottom of the trenches.

2. The method of claim 1, wherein the dielectric film is a silicon nitride film.

3. The method of claim 2, wherein the hardmask mask layer is silicon nitride.

4. The method of claim 3, wherein performing the reactive ion etch removes a portion of the hardmask mask layer from the top of the fins.

5. The method of claim 1, wherein the protective polymer coating comprises a fluocarbon polymer.

6. The method of claim 5, wherein the protective polymer coating comprises CFx.

7. The method of claim 1, wherein depositing the protective polymer coating and reactive ion etching the substrate are performed in-situ in a processing chamber without removing the substrate from the chamber.

8. The method of claim 7, wherein depositing the protective polymer coating comprises a fluorocarbon deposition and reactive ion etching the substrate comprises a CF4 etch.

9. The method of claim 8, wherein depositing the protective polymer coating is performed at a pressure of 2 to 4 Torr and an RF power of 50 to 300 W.

10. The method of claim 9, wherein depositing the protective polymer coating is performed with a flow rate of CF₄ being within 10% of a flow rate of H₂.

11. The method of claim 8, wherein reactive ion etching the substrate is performed at a pressure of 0.3-1.0 Torr, an RF power of 300-1000 W.

12. The method of claim 11, wherein reactive ion etching the substrate is performed with a flow rate of CF₄ being 2 to 4 times higher than a flow rate of H₂.

13. The method of claim 8, wherein depositing the protective polymer coating and etching are performed with the substrate at a temperature of 400-500° C.

14. The method of claim 1, wherein the substrate comprises a silicon wafer having a plurality of alternating Si/Ge and Si layers formed thereon, and the hardmask mask layer is formed on the plurality of alternating layers.

15. The method of claim 1, wherein the trenches have an aspect ratio of at least 5:1.

16. A plasma processing system, comprising:
a vacuum chamber;
a support to hold a substrate in the vacuum chamber;
a fluorocarbon gas source;
a hydrogen gas source;
one or more RF power sources to apply RF power to the vacuum chamber;
a controller coupled to the fluorocarbon gas source, the hydrogen gas source, and the one or more RF power sources and configured to flow fluorocarbon gas, hydrogen gas, and apply RF power to
cause a protective polymer coating to be deposited on a dielectric film that coats top surfaces of fins, sidewalls, and bottoms of trenches on the substrate in the vacuum chamber, and
cause the substrate to be reactive ion etched so as to preferentially remove the dielectric film and protective polymer coating from the top surfaces of the fins in comparison to the dielectric film and protective polymer coating at the bottom of the trenches.

17. The system of claim 16, wherein the controller is configured to cause the protective polymer coating to be deposited and cause the substrate to be reactive ion etched without removing the substrate from the chamber.
